(19) United States
(12) Patent Application Publication
(10) Pub. No.: US 2023/0053616 A1
(43) Pub. Date: Feb. 23, 2023

(54) APPARATUS WITH OPENABLE SLOT COVERING, AND IMAGE FORMING APPARATUS

(71) Applicant: FUJIFILM Business Innovation Corp., Tokyo (JP)

(72) Inventor: Takahiro IIZUKA, Kanagawa (JP)

(73) Assignee: FUJIFILM Business Innovation Corp., Tokyo (JP)

(21) Appl. No.: 17/553,654

(22) Filed: Dec. 16, 2021

(30) Foreign Application Priority Data
Aug. 23, 2021 (JP) 2021-135286

(51) Int. Cl. H04N 1/00; H05K 5/03; H05K 5/02

(52) U.S. Cl. CPC H04N 1/00551; H05K 5/03; H05K 5/0239

(57) ABSTRACT

An apparatus with an openable slot covering includes a housing having an openable covering that forms a part of an exterior covering and openably covers a portion of the housing, the portion having one or more slots into each of which an insertion object is insertable. The openable covering is provided as a single piece of covering that openably covers an area of the housing, the area extending from a first end of the housing to a second end of the housing and including a portion having no slots, the first end and the second end being opposite each other. The portion having no slots occupies 30% or more of the area to be covered by the openable covering.

### CROSS-REFERENCE TO RELATED APPLICATIONS

This application is based on and claims priority under 35 USC 119 from Japanese Patent Application No. 2021-135286 filed Aug. 23, 2021.

### BACKGROUND

### (i) Technical Field

The present disclosure relates to an apparatus with an openable slot covering and to an image forming apparatus.

### (ii) Related Art

An image forming apparatus including a wire covering is disclosed by Japanese Patent No. 6465637 (claim 1 and FIGS. 3, 4, and 8). The wire covering is attached to a covering member. The covering member is provided at an output portion and extends orthogonally to a sheet output direction and to the top-to-bottom direction of the image forming unit. The wire covering covers wires with which the image forming apparatus is electrically connected to optional devices.

Another image forming apparatus including a wire covering is disclosed by Japanese Patent No. 5810119 (claim 1 and FIGS. 2, 3, and 4). The wire covering includes a surrounding portion. The surrounding portion surrounds a wire cord that electrically connects an apparatus body, which includes a document reading unit, and a document feeding device to each other. The wire covering is attachable to and detachable from the apparatus body together with the wire cord.

### SUMMARY

Aspects of non-limiting embodiments of the present disclosure relate to an apparatus with an openable slot covering and an image forming apparatus each including an openable covering that forms a part of an exterior covering provided over a housing. The openable covering openably covers a portion of the housing where slots into which insertion objects are insertable individually are provided, and a portion of the housing where no such slots are provided. The exterior covering including the openable covering has no seams and therefore has an improved appearance.

Aspects of certain non-limiting embodiments of the present disclosure address the above advantages and/or other advantages not described above. However, aspects of the non-limiting embodiments are not required to address the advantages described above, and aspects of the non-limiting embodiments of the present disclosure may not address advantages described above.

According to an aspect of the present disclosure, there is provided an apparatus with an openable slot covering, the apparatus including a housing having an openable covering that forms a part of an exterior covering and openably covers a portion of the housing, the portion having one or more slots into each of which an insertion object is insertable, wherein the openable covering is provided as a single piece of covering that openably covers an area of the housing, the area extending from a first end of the housing to a second end of the housing and including a portion having no slots, the first end and the second end being opposite each other, and the portion having no slots occupies 30% or more of the area to be covered by the openable covering.

### BRIEF DESCRIPTION OF THE DRAWINGS

Exemplary embodiments of the present disclosure will be described in detail based on the following figures, wherein:

FIG. 1 is a front perspective view of an apparatus with an openable slot covering according to a first exemplary embodiment;

FIG. 2 is a front view of the apparatus illustrated in FIG. 1;

FIG. 3 is a rear perspective view of the apparatus illustrated in FIG. 1;

FIG. 4 is another rear perspective view of the apparatus illustrated in FIG. 1, with an openable covering being open;

FIG. 5 illustrates an arrangement of a portion having slots and the openable covering;

FIG. 6 illustrates another arrangement of the portion having slots and the openable covering;

FIG. 7 is a front perspective view of an image forming apparatus according to a second exemplary embodiment;

FIG. 8 is a rear perspective view of the image forming apparatus illustrated in FIG. 7;

FIG. 9 is a front view of the image forming apparatus illustrated in FIG. 7;

FIG. 10 is a right side view of the image forming apparatus illustrated in FIG. 7;

FIG. 11 is a right side view of the image forming apparatus illustrated in FIG. 7, with an openable covering being open; and

FIG. 12 is a perspective view of an apparatus according to a comparative embodiment.

### DETAILED DESCRIPTION

### First Exemplary Embodiment

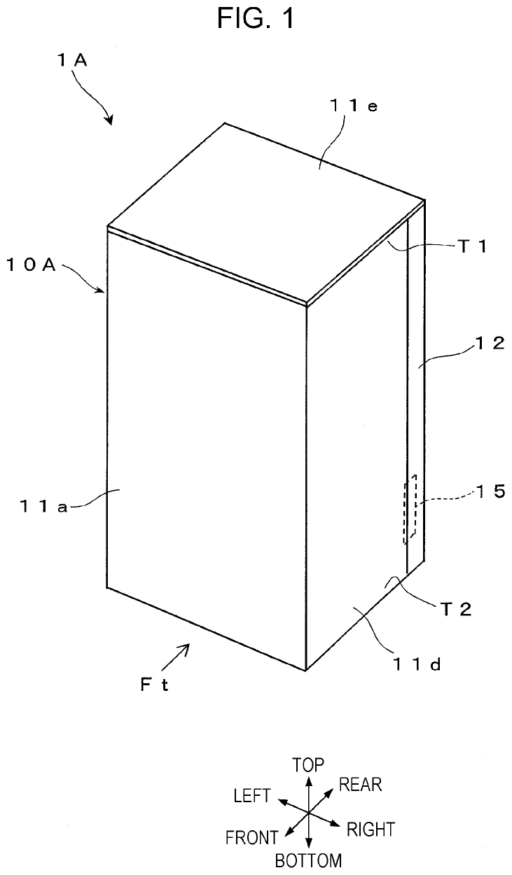

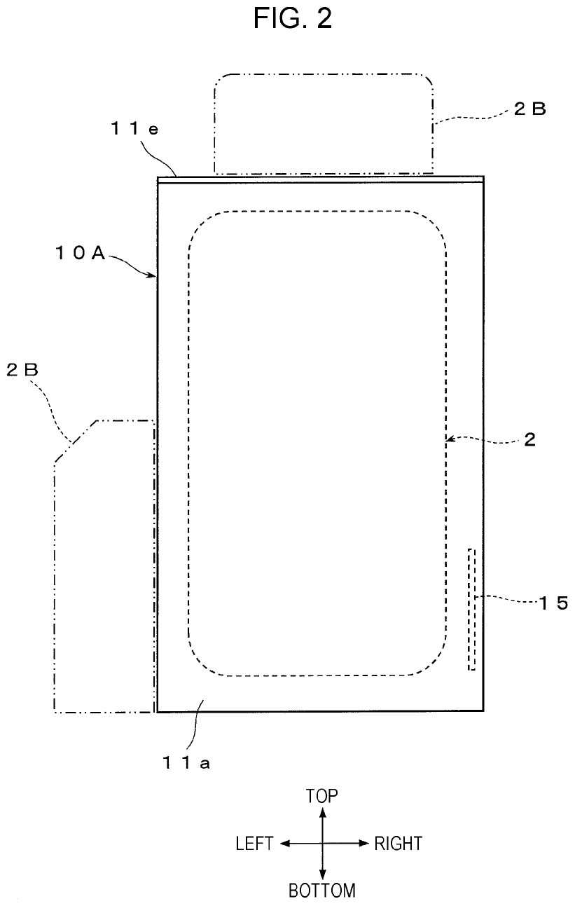

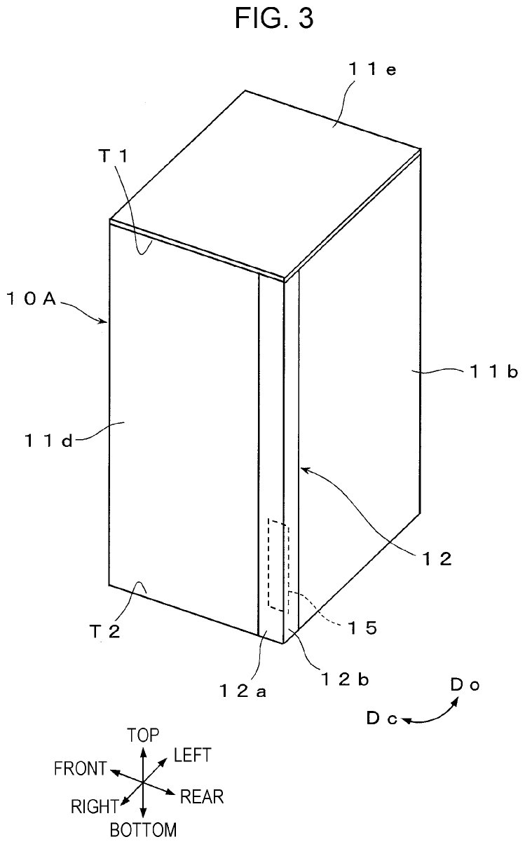

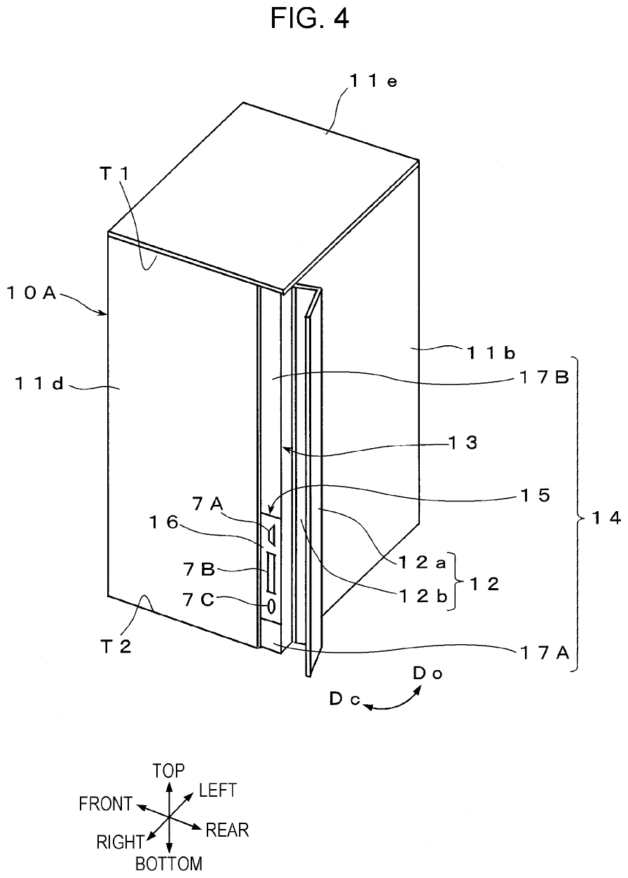

FIG. 1 is a front perspective view of an apparatus 1A with an openable slot covering according to a first exemplary embodiment of the present disclosure. FIG. 2 is a front view of the apparatus 1A. FIG. 3 is a rear perspective view of the apparatus 1A. FIG. 4 is another rear perspective view of the apparatus 1A, with an openable covering 12 being open. In FIG. 1 and other drawings, the upward, downward, leftward, rightward, frontward, and rearward directions indicated by arrows are defined with reference to a front face Ft of the apparatus 1A. The front face Ft is to be faced by a user when the user operates the apparatus 1A.

As illustrated in any of FIGS. 1 to 4, the apparatus 1A with an openable slot covering according to the first exemplary embodiment includes a housing 10A and a functional unit 2. The housing 10A houses the functional unit 2 and has the openable covering 12, which forms a part of an exterior covering 11. The openable covering 12 openably covers a portion 15, where slots 7 are provided.

The housing 10A is a structure configured and shaped as predetermined and is formed of an inner frame structure and an outer shell structure, including a plurality of frame members, a plurality of exterior covering members, and so forth.

As illustrated in FIG. 1, the housing 10A according to the first exemplary embodiment has a cubic outline elongated in the top-to-bottom direction.

The outer shell structure of the housing 10A is provided as an exterior covering 11, which includes, for example, a front covering 11a, a rear covering 11b, a left side covering, a right side covering 11d, and a top covering 11e. Since the housing 10A has a cubic outline, the covering members forming the exterior covering 11 each have a substantially rectangular shape.

As illustrated in FIGS. 1, 3, and 4, the openable covering 12 included in the exterior covering 11 forms a part of the right side covering 11d and a part of the rear covering 11b. The openable covering 12 will be described in detail separately below.

The portion 15 occupies an area having a certain size in the housing 10A and in which a plurality of slots 7 are gathered. The portion 15 is also regarded as a contact unit that allows the connection and the input and output of information between the apparatus 1A (the functional unit 2) and external devices through the slots 7 in predetermined manners.

Exemplary objects that are insertable into any of the slots 7 (hereinafter also referred to as “insertion objects”) include cables with universal-serial-bus (USB) terminals, storage devices, memory cards such as secure digital (SD) cards, information carrying media such as compact discs (CDs), information recording media, connecting cables (connection terminals of connecting cables), and the like.

The slots 7 are female connectors of various kinds that match applicable insertion objects. Examples of the slots 7 include USB terminal ports, SD card slots, slots for information carrying media and information recording media, connectors for connecting cables, and the like.

The apparatus 1A basically has a plurality of slots 7 but may have a single slot 7 if the single slot 7 occupies a relatively large area.

If the apparatus 1A has a plurality of slots 7, the slots 7 may be of the same kind or different kinds or may include slots 7 of the same kind and slots 7 of different kinds.

FIG. 4 illustrates an exemplary arrangement of slots 7A, 7B, and 7C, which are of three different kinds. If the applicable insertion objects include a CD, one of the slots 7 is provided as, for example, a slot-loading device.

In the portion 15, as illustrated in FIG. 4, the plurality of slots 7 are arranged at predetermined intervals on, for example, a supporting board 16, which has a predetermined shape and size. The supporting board 16 serving as the portion 15 having the slots 7 is formed of a part of a frame 13, included in the inner frame structure or shaped structure forming the housing 10A, or of any other relevant member such as an attachment (a bracket) or an internal partition attached to the frame 13 or the like.

The portion 15 having the slots 7 may be one of a plurality of portions 15 having slots 7 and that are defined at predetermined positions of the housing 10A. As illustrated in FIG. 4 and others, the portion 15 having the slots 7 according to the first exemplary embodiment is locally defined on the right side face of the housing 10A at a lower rear position. The portion 15 has a rectangular shape elongated in the top-to-bottom direction.

The functional unit 2 includes devices having respective functions corresponding to the usage of the apparatus 1A.

Examples of the devices applicable to the functional unit 2 include an image forming unit (20), to be described separately below, functional devices of a personal computer, video devices of a television or the like, functional devices of a household appliance such as a coffee machine, and so forth.

The functional unit 2 is not limited to a unit having a single function and may be a combination of units having different functions. When an insertion object is inserted into a corresponding one of the slots 7 for connection, the functional unit 2 is allowed to have relevant communications and other transactions with a corresponding external device.

The shape and size of the housing 10A may be changed with the kind of the functional unit 2. For example, the housing 10A may have an outline shape other than a cubic shape, or may have any shape and size with openings, recesses, and so forth.

As illustrated by a two-dot chain line in FIG. 2, the functional unit 2 may include an external functional unit 2B, which is positioned on the outside of the housing 10A. The external functional unit 2B may be provided on the top of the housing 10A, on the left or right side face of the housing 10A, or any other position of the housing 10A. If the external functional unit 2B is provided on the top of the housing 10A, the external functional unit 2B may be positioned at the center in the side-to-side direction. Examples of the external functional unit 2B include an operation unit, a display, and so forth.

In the apparatus 1A with an openable slot covering, as illustrated in FIG. 4 and others, the openable covering 12 is provided as a single piece of covering that openably covers an area 14 of the housing 10A. The area 14 extends from a first end T1 of the housing 10A to a second end T2, opposite the first end T1, of the housing 10A. The area 14 includes portions 17A and 17B of the housing 10A, where no slots 7 are provided.

The term “single piece of covering” used herein refers to a covering formed of a single solid member, not including separate members that are openable individually.

The area 14 extending from the first end T1 to the second end T2 of the housing 10A is to be covered by the openable covering 12. The area 14 is a combination of the portion 15 having the slots 7 and the portions 17A and 17B having no slots 7. The area 14 contains and extends beyond the portion 15 having the slots 7.

The first end T1 of the housing 10A according to the first exemplary embodiment is the upper end of one of the faces of the housing 10A (the right side face), and the second end T2 of the housing 10A is the lower end of that face of the housing 10A. More specifically, the first end T1 of the housing 10A is the upper end of the right side covering 11d that covers one face (the right side face) of the housing 10A. The second end T2 of the housing 10A is the lower end of the right side covering 11d.

The direction from the first end T1 to the second end T2 of the housing 10A refers to the direction of a line extending from the first end T1, passing through the portion 15 having the slot 7, and reaching the second end T2. The direction from the first end T1 to the second end T2 in the first exemplary embodiment coincides with the top-to-bottom direction of the housing 10A. The edge (corner) of the housing 10A where the right side face and the rear face meet extends in the top-to-bottom direction. Accordingly, the direction from the first end T1 to the second end T2 also coincides with the direction in which the edge extends.

The area 14 according to the first exemplary embodiment has a substantially linear strip shape (a long narrow rectangular shape) having a predetermined width and elongated in the top-to-bottom direction of the housing 10A. The portion 15 having the slots 7 is located near the edge (corner) extending in the top-to-bottom direction at the boundary between the right side face and the rear face of the housing 10A. Accordingly, the area 14 is located near the edge.

Examples of the portions 17A and 17B (hereinafter also generally referred to as “portion 17”) having no slots 7 include the following: a portion between the portion 15 having the slots 7 and the first end T1 of the housing 10A; a portion between the portion 15 having the slots 7 and the second end T2 of the housing 10A; and, if the apparatus 1A includes a plurality of portions 15 having the slots 7, a portion between adjacent ones of the portions 15 having the slots 7.

The portion 17A having no slots 7 illustrated in FIG. 4 is defined between the portion 15 having the slots 7 and the second end T2 of the housing 10A. The portion 17B having no slots 7 is defined between the portion 15 having the slots 7 and the first end T1 of the housing 10A.

If the boundary between the portion 15 having the slots 7 and each of the portions 17A and 17B having no slots 7 is not clear, the boundary may be considered as, for example, a line that extends across the area 14 to be covered by the openable covering 12 and passes through a position near the outer end of the slot 7 positioned at a corresponding one of the two ends of the portion 15 in the top-to-bottom direction of the area 14 (the line is substantially orthogonal to the long-side direction of the area 14).

As illustrated in FIG. 4 and others, the openable covering 12 of the apparatus 1A with an openable slot covering openably covers the area 14 including the portions 17A and 17B having no slots 7. The openable covering 12 is designed such that the portion 17 having no slots 7 (in the first exemplary embodiment, a combination of the portions 17A and 17B) occupies 30% or more of the area 14 to be covered by the openable covering 12.

If the portion 17 having no slots 7 occupies less than 30% of the area 14 to be covered by the openable covering 12, the portion 15 having the slots 7 occupies a relatively large part of the area 14 to be covered by the openable covering 12, making the ratio of the portion 17 having no slots 7 relatively small. In such a case, the portion 17 having no slots 7 may be provided without the openable covering 12, because such a portion having no slots 7 does not need to be openably covered, basically.

In the first exemplary embodiment, the combination of the portions 17A and 17B having no slots 7 occupies, for example, about 60% of the area 14 to be covered.

The openable covering 12 according to the first exemplary embodiment is provided as a single piece of covering that forms a part of the exterior covering 11. The exterior covering 11 is provided over at least a part (a face) of the housing 10A where the portion 15 having the slots 7 is located.

Specifically, the openable covering 12 is provided as a single piece of covering that openably covers the entirety of the area 14 that extends from the first end T1 to the second end T2 of the housing 10A, inclusive of the portion 17 (the portions 17A and 17B) of the housing 10A where no slots 7 are provided.

In other words, as illustrated in FIG. 4, the openable covering 12 is provided as a single piece of covering that openably covers the area 14, and forms a rear end part of the right side covering 11d attached to the right side face of the housing 10A where the portion 15 having the slots 7 is located.

Actually, the openable covering 12 includes a body portion 12a and a supporting portion 12b. The body portion 12a covers the area 14 extending from the first end T1 to the second end T2 of the housing 10A and is supported by the supporting portion 12b in such a manner as to be rotatable in opening and closing directions Do and Dc, which are indicated by arrows in the drawings.

The body portion 12a has a shape and a size with which the area 14 is coverable. The body portion 12a according to the first exemplary embodiment is a plate member having a rectangular shape elongated in the top-to-bottom direction. The body portion 12a or the right side covering 11d may have a grip, in the form of a recess or the like, to be gripped by the user with his/her fingers when the user opens the openable covering 12.

The supporting portion 12b has a shape and a size with which the body portion 12a is rotatably supportable. The supporting portion 12b according to the first exemplary embodiment is formed of a part of the rear covering 11b. Specifically, the supporting portion 12b is a plate member having a rectangular shape elongated in the top-to-bottom direction. The supporting portion 12b is continuous with the rear end of the body portion 12a and forms a right end part of the rear covering 11b.

As illustrated in FIG. 4, the openable covering 12 according to the first exemplary embodiment is a long narrow plate member having a generally L cross-sectional shape and is elongated linearly in the top-to-bottom direction.

The openable covering 12 is attached at the supporting portion 12b thereof to a rear part (an inner part covered by the rear covering 11b) of the housing 10A with rotatably supporting members such as hinges or rotating shafts. Thus, the openable covering 12 is rotatable on the supporting portion 12b (the rotatably supporting members) in the opening and closing directions Do and Dc indicated by the arrows in FIGS. 3 and 4, which illustrate the closed state and the open state, respectively, of the openable covering 12.

In the apparatus 1A with an openable slot covering that is configured as above, as illustrated in FIGS. 3 and 4, the entirety of the area 14 of the housing 10A including the portion 15 having the slots 7 and the portions 17A and 17B having no slots 7 is made to be covered or to be exposed to the outside with the closing or opening motion of a single member, i.e., the openable covering 12.

Therefore, as illustrated in FIGS. 1 and 3, the exterior covering 11 (in the first exemplary embodiment, the right side covering 11d and the rear covering 11b) of the apparatus 1A including the openable covering 12 has no seams that may divide the exterior covering 11 in the top-to-bottom direction.

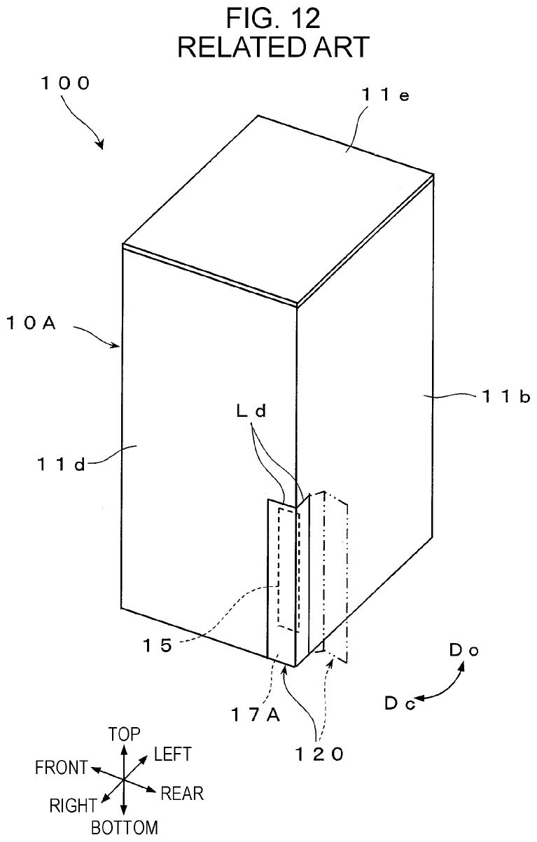

In a comparative embodiment illustrated in FIG. 12, an apparatus 100 with an openable slot covering has an openable covering 120, which openably covers only a portion 15 having slots (exactly, inclusive of a portion 17A having no slots).

In the apparatus 100 according to the comparative embodiment, an exterior covering 11 (in the comparative embodiment, a right side covering 11d and a rear covering 11b) including the openable covering 120 has a seam Ld extending laterally (actually, in the front-to-rear direction and in the side-to-side direction). In the apparatus 100 according to the comparative embodiment, the seam Ld deteriorates the appearance of the exterior covering 11.

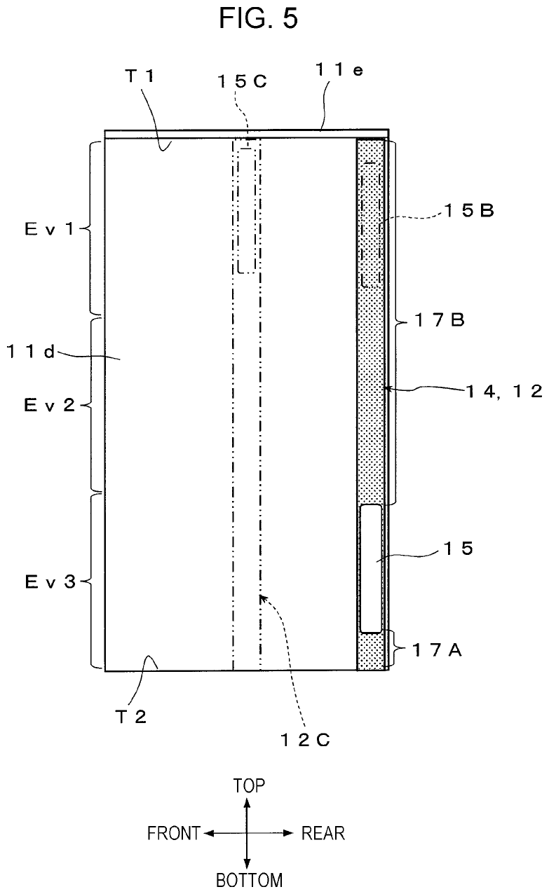

In the apparatus 1A with an openable slot covering, referring to FIG. 5, if the housing 10A is equally divided in the top-to-bottom direction into, for example, three sections: an upper section Ev1; a center section Ev2; and a lower section Ev3, the following arrangement is employed. In the apparatus 1A, for example, the slots 7 are gathered or the portion 15 having the slots 7 is locally defined in any one of the upper section Ev1, the center section Ev2, and the lower section Ev3, with the other two sections having no slots. While the portion 15 described here has a plurality of slots 7, the portion 15 may alternatively have a single slot 7.

In the first exemplary embodiment, as illustrated in FIGS. 4 and 5, the slots 7 are gathered or the portion 15 having the slots 7 is locally defined in the lower section Ev3.

If the slots 7 are gathered or the portion 15 having the slots 7 is locally defined in any one of the three sections Ev1, Ev2, and Ev3, the remainder of the area 14 (the remaining two of the three sections Ev1, Ev2, and Ev3) to be openably covered by the openable covering 12 is regarded as the portion 17 having no slots 7. In such an arrangement, the portion 17 having no slots 7 occupies at least 60% of the area 14 to be covered by the openable covering 12.

The openable covering 12 in such an arrangement is also designed to openably cover the area 14 elongated in the top-to-bottom direction, inclusive of the portion 17 having no slots 7.

### Modifications of First Exemplary Embodiment

In the apparatus 1A with an openable slot covering, the portion 15 having the slots 7 may be locally defined in each of any two of the three sections Ev1, Ev2, and Ev3, with the remaining one section having no slots.

Specifically, the following arrangements are possible: an arrangement where the portion 15 having the slots 7 is defined in each of the upper section Ev1 and the center section Ev2, an arrangement where the portion 15 having the slots 7 is defined in each of the center section Ev2 and the lower section Ev3, and an arrangement where the portion 15 having the slots 7 is defined in each of the upper section Ev1 and the lower section Ev3 (i.e., an arrangement where the portion 15 is defined at each of two opposite ends of the area 14). In any of the three arrangements, the portion 17 having no slots 7 occupies at least 30% of the area 14 to be covered by the openable covering 12. While the two portions 15 described here each have a plurality of slots 7, one of the two portions 15 may alternatively have a single slot 7.

In FIG. 5, one of the portions 15 having the slots 7 is defined in the lower section Ev3, and the other portion 15B having the slots 7 is defined in the upper section Ev1 as illustrated by a two-dot chain line.

If the apparatus 1A includes the portion 15 having the slots 7 that is locally defined in, for example, any one or each of any two of the three sections Ev1, Ev2, and Ev3, the portion (17) having no slots 7 is defined in each of the remaining two or the remaining one of the three sections Ev1, Ev2, and Ev3. That is, the portion (17) having no slots 7 occupies 30% or more of the area 14 to be covered by the openable covering 12.

The openable covering 12 of the apparatus 1A may be formed of the body portion 12a alone, without the supporting portion 12b.

The openable covering 12 including the body portion 12a alone is effective in the following arrangement, for example: as illustrated by two-dot chain lines in FIG. 5, an arrangement where a portion 15C having slots 7 is defined near the center, in the front-to-rear direction, of the right side face of the housing 10A, with the openable covering 12 being provided near the center, in the front-to-rear direction, of the right side covering 11d.

In the apparatus 1A, the location of the portion 15 having the slots 7 is not limited to a position on the right side face of the housing 10A and may be a position on the front face, the left side face, the rear face, or the top face of the housing 10A.

In such an arrangement, the openable covering 12 is to form, for example, a part of the front covering 11a, a part of the left side covering, a part of the rear covering 11b, or a part of the top covering 11e.

The portion 15 having the slots 7 may be defined in each of a plurality of faces of the housing 10A among the five faces: the front face, the left side face, the right side face, the rear face, and the top face.

In such an arrangement, the openable covering 12 may be provided for each of all the plurality of faces of the housing 10A where the portions 15 having the slots 7 are defined, or for each of some of the plurality of faces.

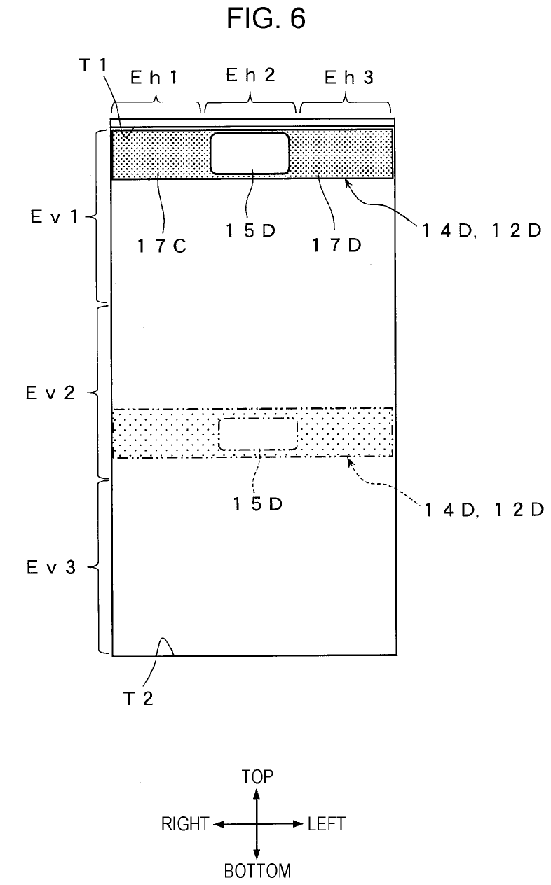

In the apparatus 1A, as illustrated in FIG. 6 for example, the portion 15 having the slots 7 may be a portion 15D, which is elongated in the side-to-side direction at the upper end (in the upper section Ev1) of the rear face of the housing 10A. In such an arrangement, an openable covering 12D may be designed as follows. The openable covering 12D covers an area 14D, which contains and extends beyond the portion 15D having the slots 7 in the side-to-side direction (from the left end to the right end).

The openable covering 12D has a long narrow shape elongated in the side-to-side direction and is provided as a part (at the upper end) of the rear covering 11b. The openable covering 12D may be attached to the upper end of the rear face of the housing 10A or the rear covering 11b in such a manner as to be openable by rotating rearward on, for example, the lower end thereof.

FIG. 6 illustrates an arrangement where the housing 10A is equally divided in the side-to-side direction into three sections: a right section Eh1; a center section Eh2; and a left section Eh3, and the portion 15D having the slots 7 and elongated in the side-to-side direction is locally defined in the center section Eh2.

In such an arrangement, the right section Eh1 and the left section Eh3 that are adjacent to the portion 15D having the slots 7 on the right and left sides, respectively, are regarded as portions 17C and 17D each having no slots.

As illustrated by two-dot chain lines in FIG. 6, the area 14D, inclusive of the portion 15D having the slots 7, and the openable covering 12D that are elongated in the side-to-side direction may alternatively be located in the center section Ev2 or the lower section Ev3 of the housing 10A that are defined in the top-to-bottom direction.

### Second Exemplary Embodiment

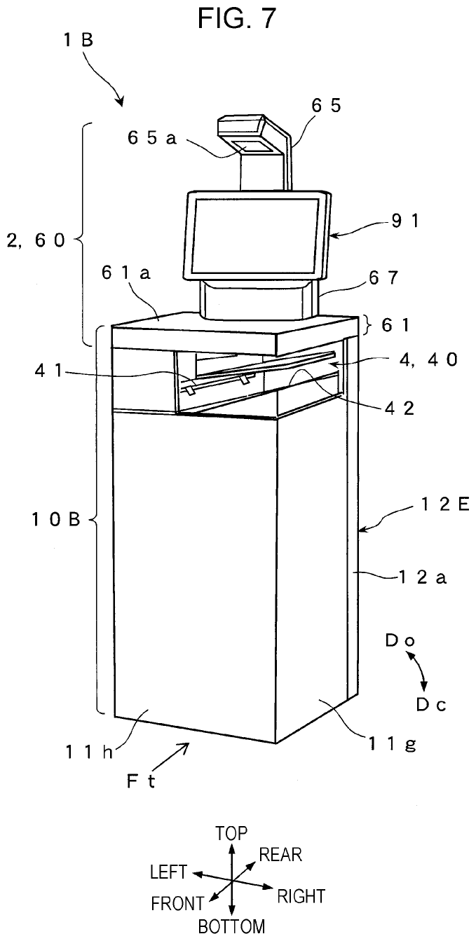

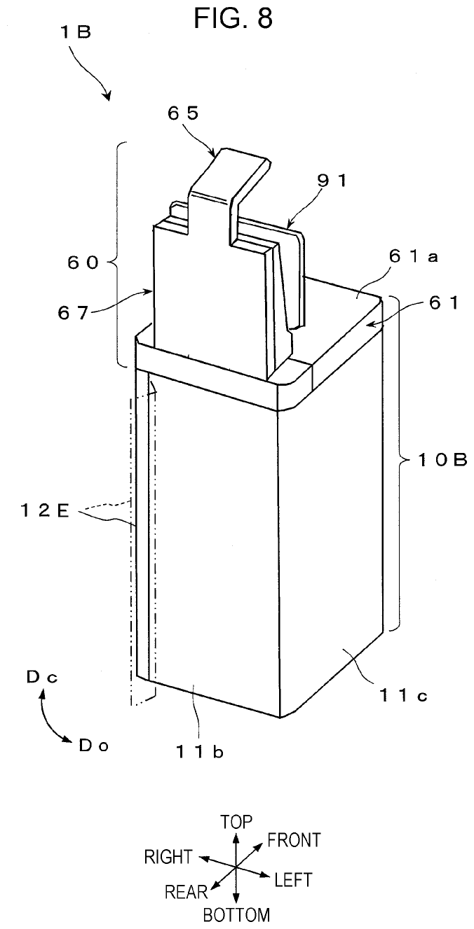

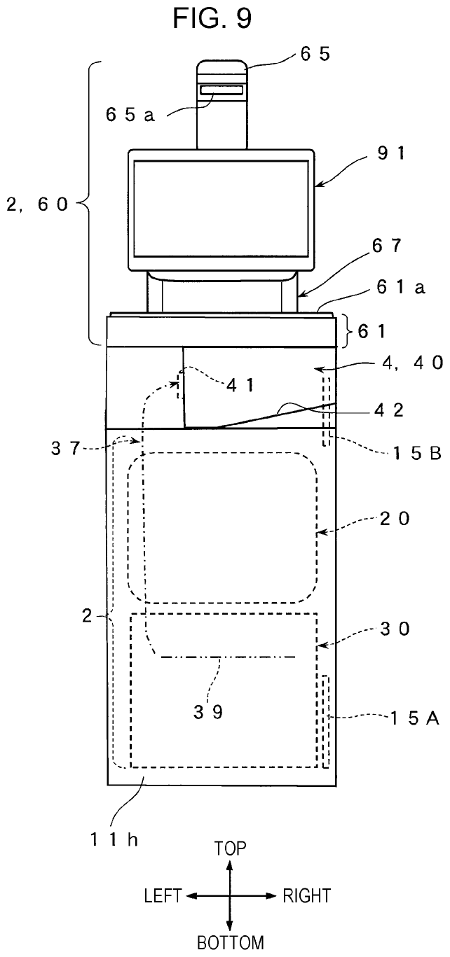

FIG. 7 is a front perspective view of an image forming apparatus 1B, which is an exemplary apparatus with an openable slot covering according to a second exemplary embodiment of the present disclosure. FIG. 8 is a rear perspective view of the image forming apparatus 1B. FIG. 9 is a front view of the image forming apparatus 1B.

The image forming apparatus 1B according to the second exemplary embodiment has the same configuration as the apparatus 1A according to the first exemplary embodiment, except the following: as illustrated in any of FIGS. 7 to 9, the image forming apparatus 1B includes a housing 10B, which includes a medium output portion 4; the housing 10B has the portion 15B having the slots 7; and the functional unit 2 includes the following subunits: an image forming unit 20, a medium supplying unit 30, and an external reading unit 60.

In the following description, elements that are the same as those described in the first exemplary embodiment are denoted by corresponding ones of the reference signs used in the first exemplary embodiment, and description of those elements is omitted unless necessary.

The housing 10B is almost the same as the housing 10A according to the first exemplary embodiment, except that the housing 10B has no top covering 11e because the external reading unit 60 is provided at the top thereof, and that the housing 10B includes the medium output portion 4, which is an in-frame space where a recording medium 39 having an image formed thereon by the image forming unit 20 is to be outputted.

As illustrated in FIG. 7 and others, the housing 10B has a cubic outline elongated in the top-to-bottom direction, which is almost the same as the shape of the housing 10A according to the first exemplary embodiment. The exterior covering of the housing 10B includes a front covering 11h and a right side covering 11g, which are different from the front covering 1la and the right side covering 11d according to the first exemplary embodiment in the shapes thereof (in having cuts) that are designed in conformity with the medium output portion 4.

The front covering 11h is, for example, an openable covering that openably covers the housing 10B, with the medium output portion 4 and a portion (a base 61) of the external reading unit 60 being exposed.

The front covering 11h serving as an openable covering may be shaped in such a manner as to additionally expose the medium supplying unit 30 provided in the housing 10B. In that case, the front covering 11h is regarded as an openable covering that openably covers the image forming unit 20 provided in the housing 10B.

The medium output portion 4 receives a recording medium 39 to be outputted thereto after an image is formed thereon by the image forming unit 20.

The medium output portion 4 is positioned on the upper right side with respect to the image forming unit 20.

The medium output portion 4 serves as a receiving space 40, which is provided in an upper part of the housing 10B and on the front face Ft of the housing 10B.

The medium output portion 4 has an outlet 41 in the left inner wall of the receiving space 40, and a placing surface 42 at the bottom of the receiving space 40. The recording medium 39 is to be outputted from the outlet 41 and to be placed onto the placing surface 42. The placing surface 42 forms, for example, a slope that inclines upward while extending rightward from the outlet 41.

The image forming unit 20 as one of the subunits of the functional unit 2 includes devices configured to form an image corresponding to image information on a recording medium 39.

The image forming unit 20 includes an electrophotographic imaging device configured to form an image with developer eventually on a recording medium 39.

The electrophotographic imaging device in the image forming unit 20 includes a charging device, an exposure device, a developing device, a transfer device, and so forth (not illustrated), all of which are provided around an image carrier (not illustrated) such as a photoconductor. The image forming unit 20 further includes a fixing device provided at a position away from the image carrier. The image forming unit 20 further includes a developer supplying device, an image processor, a controller, and other relevant devices.

The transfer device may employ either a direct transfer method in which an image formed with developer on the image carrier is directly transferred to a recording medium 39, or an intermediate transfer method in which an image formed with developer on the image carrier is transferred to an intermediate transfer member and then to a recording medium 39.

The image forming unit 20 has a function of forming an image corresponding to image information received from an external device, such as an information terminal, connected to the image forming apparatus 1B, and a function of forming an image corresponding to image information acquired through the reading of a reading object by the external reading unit 60.

In the image forming unit 20, the imaging device performs a charging operation, an exposure operation corresponding to image information, a developing operation, and a transfer operation in that order on and around the image carrier. Thus, in the image forming unit 20, an image is formed with developer on the image carrier, and the image is then transferred from the image carrier to a recording medium 39. In the image forming unit 20, a fixing operation is further performed on the recording medium 39 having the image transferred thereto. Thus, the image is fixed to the recording medium 39. The recording medium 39 having the fixed image is eventually outputted to the medium output portion 4.

The medium supplying unit 30 stores recording media 39 and supplies the recording media 39 one by one to the image forming unit 20.

The medium supplying unit 30 is provided below the image forming unit 20.

The medium supplying unit 30 includes a storing member such as a tray in which the recording media 39 are stored, a feeding device that feeds out the recording media 39 one by one from the storage member, and so forth (all not illustrated).

The storage member is drawable from the inside of the housing 10B to the outside, so that recording media 39 are to be placed thereon. The storage member may be one of a plurality of storage members. The feeding device is provided for each of the storage members.

The recording medium 39 may be any of the following media in the form of a sheet having a predetermined size: plain paper, coated paper, thick paper, and the like.

In the medium supplying unit 30, a predetermined one of the recording media 39 is fed toward the image forming unit 20 in synchronization with the transfer operation performed by the image forming unit 20. The recording medium 39 that is fed out of the medium supplying unit 30 is transported to the outlet 41 at the medium output portion 4 through a part of the image forming unit 20 (a part where an image is transferred to the recording medium 39) along a medium transport path 37, which is illustrated by a one-dot chain line in FIG. 9.

The external reading unit 60 as one of the subunits of the functional unit 2 reads a reading object on the outside of the housing 10B.

As illustrated in FIG. 7 and others, the external reading unit 60 includes the base 61, on which a reading object is to be placed; a reading device 65, which reads the reading object to be placed on the base 61; and so forth.

The base 61 is a plate member having a top face 61a, which is flat so that the reading object is to be placed still thereon. The base 61 is attached to the upper end of the housing 10B such that the top face 61a forms the top face of the housing 10B.

The reading object to be placed on the base 61 is at least readable from above the base 61 by the reading device 65 and may be, for example, a sheet-type document having image information recorded thereon, or a three-dimensional object such as a book, a magazine, a food product, a plant, or the like.

The reading device 65 includes a reader 65a, a supporting member 67, and so forth. The reader 65a is supported by the supporting member 67 and is capable of optically reading the reading object placed on the base 61. In the reading device 65 according to the second exemplary embodiment, the supporting member 67 extends upward by a predetermined length from the rear end of the base 61 and supports the reader 65a such that the reader 65a is oriented toward the base 61 for reading.

The reader 65a is, for example, a camera including a combination of an imaging device such as a charge-coupled device (CCD) and optical members such as lenses. The camera employed as the reader 65a is also referred to as “document camera”. The reading device 65 may include an illuminator that illuminates the reading object on the base 61 when the reading object is to be read.

As illustrated in FIG. 9 and others, the reading device 65 includes an operation panel 91, on which the image forming apparatus 1B is to be operated. The operation panel 91 is provided at a position near the base of the supporting member 67 and on the front of the supporting member 67. The operation panel 91 is positioned above the base 61 with a space interposed therebetween in view of increased operability and other factors. The operation panel 91 basically includes a display such as a liquid-crystal touch panel on which an operation screen is displayed to be operated. The operation panel 91 may further include mechanical operation members such as buttons.

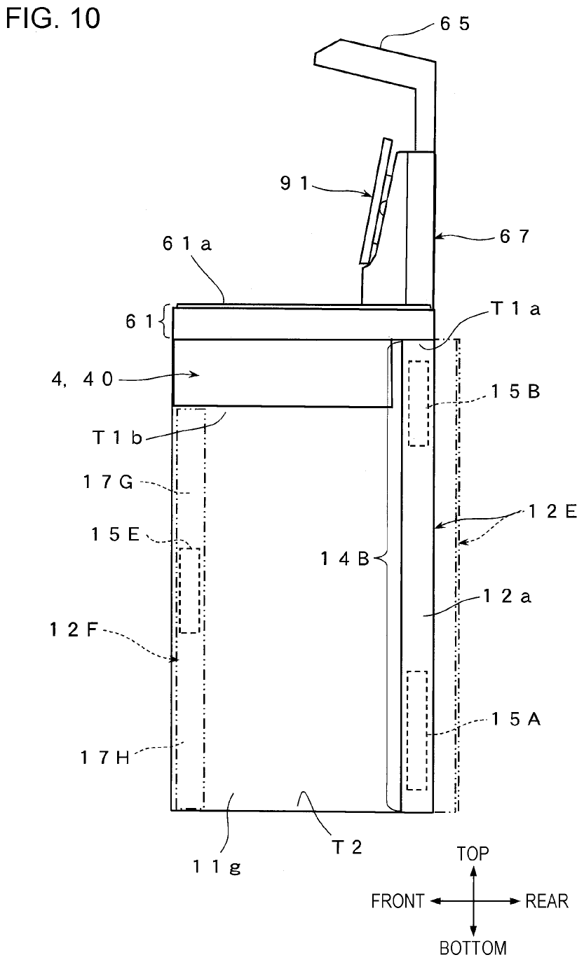

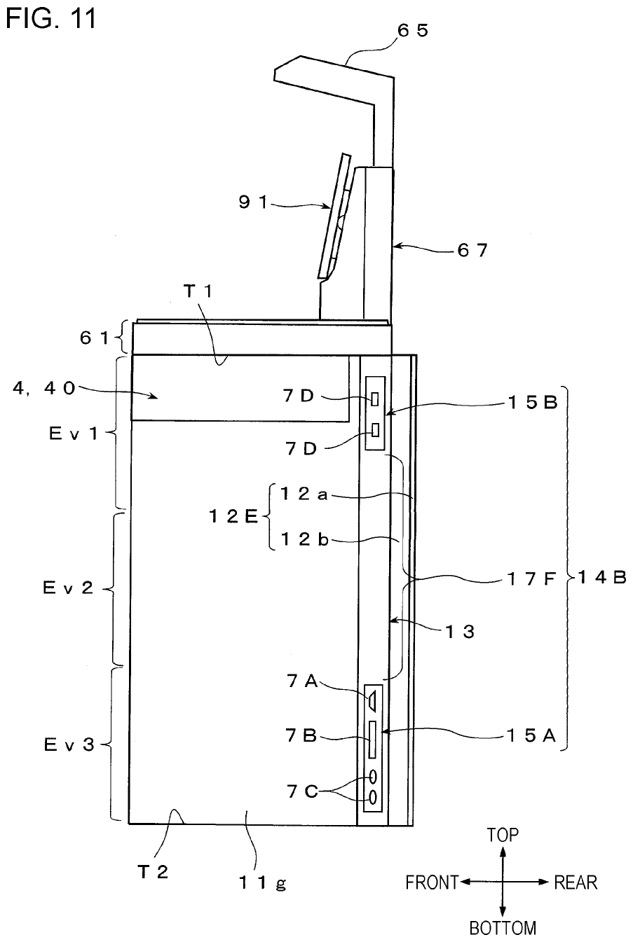

As illustrated in FIGS. 10 and 11, the image forming apparatus 1B has two portions 15 having the slots 7: portions 15A and 15B. The portions 15A and 15B each have slots 7 and are locally defined in a rear part of the right side face of the housing 10B, at the lower end and the upper end, respectively.

The portion 15A at the lower end has three kinds of slots 7A, 7B, and 7C, including two slots 7C. The slots 7A to 7C are arranged at intervals in the top-to-bottom direction. The portion 15B at the upper end has two slots 7D, which are of the same kind and are arranged at an interval in the top-to-bottom direction. The image forming apparatus 1B may have a single portion 15 having the slots 7, i.e., only one of the portion 15A at the lower end and the portion 15B at the upper end.

In the image forming apparatus 1B, as illustrated in FIG. 11, the right side covering 11g includes an openable covering 12E at the rear end thereof. The openable covering 12E forms a part of the exterior covering 11 and openably covers the two portions 15A and 15B having the slots 7. As illustrated in FIG. 10 and others, the openable covering 12E is provided as a single piece of covering that openably covers the area 14B extending from the first end T1 (the upper end) of the housing 10B to the second end T2 (the lower end) of the housing 10B in the top-to-bottom direction, inclusive of a portion 17F of the housing 10B, where no slots 7 are provided.

In the image forming apparatus 1B, as illustrated in FIG. 10, the first end T1 (the upper end) is not the upper end of the housing 10B but the upper end of a rear part of the right side covering 11g included in the exterior covering 11. In other words, the first end T1 according to the second exemplary embodiment is regarded as an upper end T1a of the rear part of the right side covering 11g, ignoring the base 61 of the external reading unit 60 provided at the top of the housing 10B.

As illustrated in FIG. 11, the openable covering 12E of the image forming apparatus 1B openably covers the area 14B including the portion 17F having no slots 7. The portion 17F having no slots 7 occupies 30% or more of the area 14B to be covered by the openable covering 12E.

In the second exemplary embodiment, more specifically, the portion 17F having no slots 7 occupies, for example, about 50% of the area 14B to be covered.

As with the case of the openable covering 12 according to the first exemplary embodiment, substantially, the openable covering 12E includes a body portion 12a and a supporting portion 12b. The body portion 12a covers the area 14B extending from the first end T1 of the housing 10B to the second end T2 of the housing 10B. The supporting portion 12b supports the body portion 12a such that the body portion 12a is rotatable in the opening and closing directions Do and Dc indicated by the arrows in FIG. 7.

Details of the slots 7A to 7D, the portions 15A and 15B having the slots 7D and others, the openable covering 12E, and other relevant elements are substantially the same as those of the slots 7A and others, the portion 15 having the slots 7A and others, the openable covering 12, and other relevant elements according to the first exemplary embodiment.

In the image forming apparatus 1B configured as above, as illustrated in FIG. 11, the entirety of the area 14B of the housing 10B including the portions 15A and 15B having the slots 7A and others and the portion 17F having no slots 7A nor others is made to be covered or to be exposed to the outside with the closing or opening motion of a single member, i.e., the openable covering 12.

Therefore, as illustrated in FIGS. 7, 8, 10, and 11, the exterior covering 11 (in the second exemplary embodiment, the right side covering 11g and the rear covering 11b) of the image forming apparatus 1B including the openable covering 12E has no seams Ld (see FIG. 12) that may divide the exterior covering 11.

### Modifications

The present disclosure is not limited to the first and second exemplary embodiments and includes the following modifications, for example.

The modifications of the first exemplary embodiment may also be applied to some of the elements according to the second exemplary embodiment such as the portion 15B having the slots 7, the portion 17F having no slots 7, and the openable covering 12E.

For example, in the image forming apparatus 1B, as illustrated in FIG. 10, if a portion 15E having slots is defined on the right side face of the housing 10B, an openable covering 12F may be provided at the front end of the right side covering 11g, as a part of the exterior covering 11 and in such a manner as to openably cover the portion 15E.

The openable covering 12F in such a modification is provided as a single piece of covering that openably covers an area extending from the first end T1 (the upper end) of the housing 10B to the second end T2 (the lower end) of the housing 10B in the top-to-bottom direction, inclusive of portions 17G and 17H of the housing 10B, where no slots 7 are provided.

In such a modification, as illustrated in FIG. 10, the first end T1 (the upper end) is not the upper end of the housing 10B but the upper end of a front part of the right side covering 11g included in the exterior covering 11. In other words, the first end T1 in such a modification is regarded as an upper end T1b of the front part of the right side covering 11g, at the boundary between the right side covering 11g and the medium output portion 4 provided at the top of the housing 10B.

The housing 10 is not limited to a structure, such as the housing 10A or 10B according to the first and second exemplary embodiments, having a substantially cubic outline elongated in the top-to-bottom direction and may be, for example, a housing 10 having curved side faces.

The image forming apparatus may be an image forming apparatus obtained by omitting the external reading unit 60 from the image forming apparatus 1B according to the second exemplary embodiment. In that case, the upper end of the housing 10B, on which the external reading unit 60 is provided in the second exemplary embodiment, may be covered by, for example, the top covering 11e (see FIG. 1 and others) that forms a part of the exterior covering 11.

The image forming unit 20 of the image forming apparatus is not limited to an electrophotographic image forming unit that uses developer and may be an image forming unit 20 based on another image forming method (such as an inkjet method).

If the image forming unit 20 and the medium supplying unit 30 are arranged side by side in the side-to-side direction of the image forming apparatus, the openable covering forming a part of the exterior covering 11 may be designed in such a manner as to openably cover both the image forming unit 20 and the medium supplying unit 30 arranged in the side-to-side direction.

The foregoing description of the exemplary embodiments of the present disclosure has been provided for the purposes of illustration and description. It is not intended to be exhaustive or to limit the disclosure to the precise forms disclosed. Obviously, many modifications and variations will be apparent to practitioners ski11e d in the art. The embodiments were chosen and described in order to best explain the principles of the disclosure and its practical applications, thereby enabling others ski11e d in the art to understand the disclosure for various embodiments and with the various modifications as are suited to the particular use contemplated. It is intended that the scope of the disclosure be defined by the following claims and their equivalents.

What is claimed is:

1. An apparatus with an openable slot covering, comprising:
a housing having an openable covering that forms a part of an exterior covering and openably covers a portion of the housing, the portion having one or more slots into each of which an insertion object is insertable,
wherein the openable covering is provided as a single piece of covering that openably covers an area of the housing, the area extending from a first end of the housing to a second end of the housing and including a portion having no slots, the first end and the second end being opposite each other; and
wherein the portion having no slots occupies 30% or more of the area to be covered by the openable covering.

2. An image forming apparatus comprising:
an image forming unit that forms an image; and
a housing having an openable covering that forms a part of an exterior covering and openably covers a portion of the housing, the portion having one or more slots into each of which an insertion object is insertable,
wherein the openable covering is provided as a single piece of covering that openably covers an area of the housing, the area extending in a top-to-bottom direction of the housing and including a portion having no slots; and
wherein the portion having no slots occupies 30% or more of the area to be covered by the openable covering.

3. The apparatus with an openable slot covering, according to claim 1,
wherein the one or more slots are gathered in one of or each of two of sections of the area extending from the first end of the housing to the second end of the housing, the sections being at the first and second ends and at a center between the first end and the second end, respectively.

4. The image forming apparatus according to claim 2,
wherein the one or more slots are gathered in one of or each of two of upper, lower, and center sections of the area extending in the top-to-bottom direction of the housing.

5. The apparatus with an openable slot covering, according to claim 3,
wherein the one or more slots are provided in each of the sections of the area that are at the first and second ends, respectively, with no slots being provided between the sections at the first and second ends.

6. The image forming apparatus according to claim 4,
wherein the one or more slots are provided in each of the upper and lower sections of the area, with no slots in the center section.
